(19) United States
(12) Patent Application Publication
(10) Pub. No.: US 2004/0150061 A1
(43) Pub. Date: Aug. 5, 2004

(54) Package structure of a photosensor

(76) Inventor: Chung Hsien Hsin, Chupei (TW)

Correspondence Address: PRO-TECHTOR INTERNATIONAL SERVICES, 20775 Norada Court, Saratoga, CA, 95070-3018, US

(21) Appl. No.: 10/356,758

(22) Filed: Jan. 30, 2003

(51) Int. Cl. H01L 31/0203

(52) U.S. Cl. 257/433

(57) ABSTRACT

A package structure of a photosensor of the invention includes a frame layer, a substrate, a photosensitive chip, wires, and a transparent layer. The frame layer has an upper surface, a lower surface, and a slot penetrating through the frame layer from the upper surface to the lower surface. The upper surface is formed with first connection points and the lower surface is formed with second connection points. The substrate is formed in the slot of the frame layer and is formed with a cavity within the slot. The photosensitive chip is arranged on the substrate and within the cavity. The wires electrically connect the chip to the first connection points, respectively. The transparent layer is arranged on the upper surface of the frame layer to cover the chip so that the chip may receive optical signals passing through the transparent layer.

### BACKGROUND OF THE INVENTION

1. Field of the Invention

The invention relates to a package structure of a photosensor, and in particular to a photosensor having a reduced manufacturing cost and package volume.

2. Description of the Related Art

A general sensor is used for sensing signals, which may be optical or audio signals. The sensor of the invention is used to receive image signals or optical signals. After receiving image signals, the photosensor converts the image signals into electrical signals, which are then transmitted to a printed circuit board via a substrate.

Referring to FIG. 1, a conventional photosensor-includes a substrate 10, a frame layer 12, a photosensitive chip 14, a plurality of wires 15, and a transparent layer 22. The substrate 10 has an upper surface 11 on which signal input terminals 18 are formed, and a lower surface 13 on which signal output terminals 24 are formed. The frame layer 12 is arranged on the substrate 10 to form a cavity 16 together with the substrate 10. The photosensitive chip 14 is arranged on the substrate 10 and within the cavity 16. A plurality of bonding pads 20 is formed on the photosensitive chip 14. The wires 15 electrically connect the bonding pads 20 of the photosensitive chip 14 to the signal input terminals 18 of the substrate 10, respectively. The transparent layer 22 is coated with an adhesive layer 23 and arranged on the frame layer 12 to cover and encapsulate the photosensitive chip 14.

However, the above-mentioned photosensor has the following drawbacks.

1. Since the substrate 10 is a ceramic substrate or FR4 printed circuit board on which traces are formed to form signal input terminals 18 and signal output terminals 24, the overall volume of the substrate 10 is large, the material cost is high, and the package cost is relatively high.

2. Since a gap for wire bonding has to be maintained between the substrate 10 and the frame layer 12, the package volume is large and the product cannot be miniaturized.

### SUMMARY OF THE INVENTION

An object of the invention is to provide a package structure of a photosensor having lower material and manufacturing costs.

Another object of the invention is to provide a package structure of a photosensor having a reduced package volume.

To achieve the above-mentioned objects, the invention provides a package structure of a photosensor including a frame layer, a substrate, a photosensitive chip, a plurality of wires, and a transparent layer. The frame layer has an upper surface, a lower surface, and a slot penetrating through the frame layer from the upper surface to the lower surface. The upper surface is formed with a plurality of first connection points and the lower surface is formed with second connection points. The substrate is formed in the slot of the frame layer and is formed with a cavity within the slot. The photosensitive chip is arranged on the substrate and within the cavity. The wires electrically connect the photosensitive chip to the first connection points of the frame layer, respectively. The transparent layer is arranged on the upper surface of the frame layer to cover the photosensitive chip so that the photosensitive chip may receive optical signals passing through the transparent layer.

### BRIEF DESCRIPTION OF THE DRAWINGS

FIG. 1 is a schematic illustration showing a package structure of a conventional photosensor.

FIG. 2 is a cross-sectional view showing a package structure of a photosensor according to an embodiment of the invention.

FIG. 3 is a top view showing a frame layer of the photosensor of the invention.

FIG. 4 is a schematic illustration showing a combination of the frame layer and the substrate of the invention.

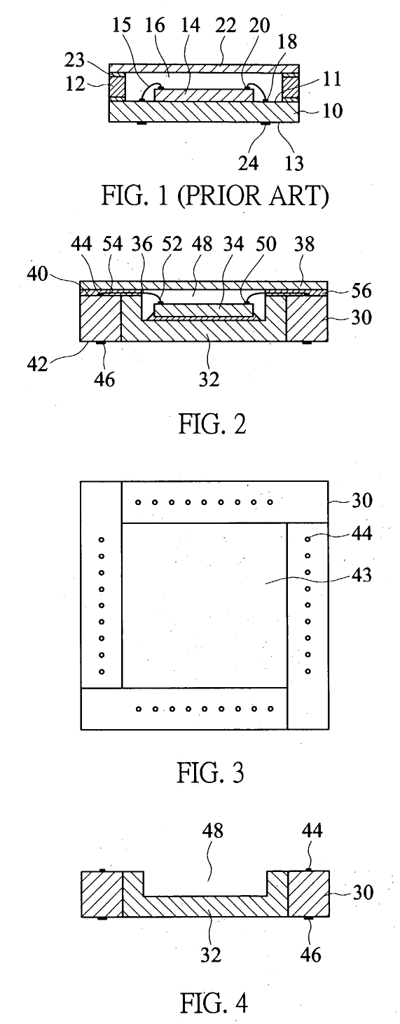

### DETAILED DESCRIPTION OF THE INVENTION

Referring to FIG. 2, a package structure of a photosensor according to an embodiment of the invention includes a frame layer 30, a substrate 32, a photosensitive chip 34, a plurality of wires 36 and a transparent layer 38.

Please refer to FIGS. 3 and 2. The frame layer 30 may be a ceramic or FR4 printed circuit board having an upper surface 40, a lower surface 42, and a slot 43 penetrating through the frame layer 30 from the upper surface 40 to the lower surface 42. The upper surface 40 is formed with first connection points 44 and the lower surface 42 is formed with second connection points 46 electrically connected to the first connection points 44, respectively.

Please refer to FIGS. 4 and 2. The substrate 32 is made of plastic or rubber material and is formed in the slot 43 of the frame layer 30 by way of injection molding or die pressing. In addition, the substrate 32 is formed with a cavity 48.

The photosensitive chip 34 has a plurality of bonding pads 50 and is arranged on the substrate 32 and within the cavity 48.

Each of the wires 36 has a first terminal 52 and a second terminal 54. The first terminals 52 are electrically connected to the bonding pads 50 of the photosensitive chip 34, and the second terminals 54 are electrically connected to the first connection points 44 of the frame layer 30, respectively. Therefore, signals from the photosensitive chip 34 may be transferred to the frame layer 30.

The transparent layer 38 is a piece of transparent glass and is adhered to the upper surface 40 of the frame layer 30 by an adhesive layer 56 to cover the photosensitive chip 34. Then, the photosensitive chip 34 may receive optical signals passing through the transparent layer 38. In addition, the adhesive layer 56 also surrounds and seals the second terminals 54 and the wires 36 to prevent the wires 36 from being damaged by the transparent layer 38.

According to the above-mentioned structure, the photosensor of the invention has the following advantages.

1. Since traces are formed on the frame layer 30 and used to form the first connection points 44 and the second connection points 46, the used ceramic or FR4 printed circuit board is smaller. In addition, since the substrate 32 with larger area is made of a low-cost plastic or rubber material, the overall package cost may be effectively lowered.

2. Since the wires 36 are bonded to the upper surface 40 of the frame layer 30, the gap between the frame layer 30 and the photosensitive chip 34 may be omitted, the package volume may be effectively lowered, and the product may be effectively miniaturized.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

What is claimed is:

1. A package structure of a photosensor, comprising:
a frame layer having an upper surface, a lower surface and a slot penetrating through the frame layer from the upper surface to the lower surface, the upper surface being formed with a plurality of first connection points, and the lower surface being formed with second connection points;
a substrate formed in the slot of the frame layer, the substrate being formed with a cavity;
a photosensitive chip having a plurality of bonding pads, arranged on the substrate and within the cavity;
a plurality of wires for electrically connecting the bonding pads of the photosensitive chip to the first connection points of the frame layer, respectively; and
a transparent layer arranged on the upper surface of the frame layer to cover the photosensitive chip so that the photosensitive chip receives optical signals passing through the transparent layer.

2. The package structure according to claim 1, wherein the frame layer is a FR4 printed circuit board.

3. The package structure according to claim 1, wherein the substrate is made of a plastic or rubber material.

4. The package structure according to claim 1, wherein the substrate is formed by way of injection molding or die pressing.

5. The package structure according to claim 1, wherein the transparent layer is a piece of transparent glass.

6. The package structure according to claim 1, wherein an adhesive layer is applied to the upper surface of the frame layer to surround and seal the plurality of wires.
